(19) United States
(12) Patent Application Publication
(10) Pub. No.: US 2004/0232562 A1
(43) Pub. Date: Nov. 25, 2004

(54) System and method for increasing bump pad height

(75) Inventors: Edgardo Rulloda Hortaleza, Garland, TX (US); Glenn Enrick Calderon Cosue, Baguio City (PH); Rodel Belarmino Arquisal, Baguio City (PH)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/445,164

(22) Filed: May 23, 2003

(51) Int. Cl. H01L 23/48; H01L 23/52; H01L 29/40

(52) U.S. Cl. 257/778; 257/738; 257/737

(57) ABSTRACT

In accordance with the present invention, a system and method for increasing bump pad height in a flip chip assembly are provided. The method includes depositing a bump pad on a substrate and depositing a solder mask on the substrate to define an opening surrounding the bump pad. A resist material is then deposited on the substrate such that the resist material covers the bump pad and solder mask. The resist material is then etched to form a column-shaped opening above the bump pad, and a conductive material is deposited into the column-shaped opening. The remaining resist material may then be optionally removed, leaving behind a column of conductive material above the bump pad.

### TECHNICAL FIELD OF THE INVENTION

The present invention relates in general to semiconductor manufacturing and, in particular, to a system and method for increasing bump pad height in a flip chip assembly.

### BACKGROUND OF THE INVENTION

Flip chips are microelectronic devices in which a silicon chip, or die, is attached facedown to a substrate via a plurality of small solder bumps. In general, a die attach system “picks and flips” the die directly from a silicon wafer and places the die on the substrate using a plurality of solder bumps to form an electrical connection with a plurality of bump pads disposed upon the surface of the substrate. Once the solder has been reflowed and solidified to form a rigid coupling between the die and the substrate, a non-conductive underfill material is typically inserted between the die and substrate to strengthen the connection between the two and to provide a barrier to moisture or other contaminants.

As chip sizes have decreased over time, flip chip assemblies have also decreased in size. These smaller chip sizes require narrower bump pitches and, therefore, smaller bump sizes. This typically results in the flip chip having a decreased stand-off height between the die and the substrate, which may increase the level of stress at the connection between the solder bumps and die due to the differences in the coefficients of thermal expansion (CTE) of the two materials. Additionally, the decreased stand-off height may make inserting an underfill material more challenging as many underfill materials resist flowing between a die and substrate with a small stand-off height.

### SUMMARY OF THE INVENTION

In accordance with the present invention, a system and method for increasing bump pad height in a flip chip assembly are provided. The method comprises depositing a bump pad on a substrate and depositing a solder mask on the substrate to define an opening surrounding the bump pad. A resist material is then deposited on the substrate such that the resist material covers the bump pad and solder mask. The resist material is then etched to form a column-shaped opening above the bump pad, and a conductive material is deposited into the column-shaped opening. The remaining resist material may then be optionally removed, leaving behind a column of conductive material above the bump pad.

Technical advantages of particular embodiments of the present invention include a flip chip assembly having an increased bump pad height. This increased height in turn increases the stand-off height of the flip chip assembly and helps to reduce the stress due to any CTE differences experienced at the connection between the die and the solder bump.

Another technical advantage of particular embodiments of the present invention is a flip chip assembly that includes a resist material deposited over the solder mask that approximates the properties of the underfill material inserted between the die and substrate. This allows the resist material to be left in place on the solder mask and essentially function as part of the underfill.

Other technical advantages will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present invention and its advantages, reference is now made to the following descriptions, taken in conjunction with the accompanying drawings, in which:

FIG. 1 illustrates a side-view of a flip chip assembly in accordance with a particular embodiment of the present invention having an increased bump pad height;

FIG. 2A illustrates a side-view of the substrate of a flip chip assembly in accordance with a particular embodiment having a resist material deposited over the bump pad and solder mask of the substrate;

FIG. 2B illustrates a side-view of the substrate of FIG. 2A having a column-shaped opening etched into the resist material above the bump pad;

FIG. 2C illustrates a side-view of the substrate of FIG. 2B having a conductive material deposited into the column-shaped opening above the bump pad;

FIG. 2D illustrates a side-view of the substrate of FIG. 2C having the remaining resist material covering the substrate removed; and

FIG. 3 illustrates a flowchart of a method of increasing bump pad height in accordance with a particular embodiment of the present invention.

### DETAILED DESCRIPTION OF THE INVENTION

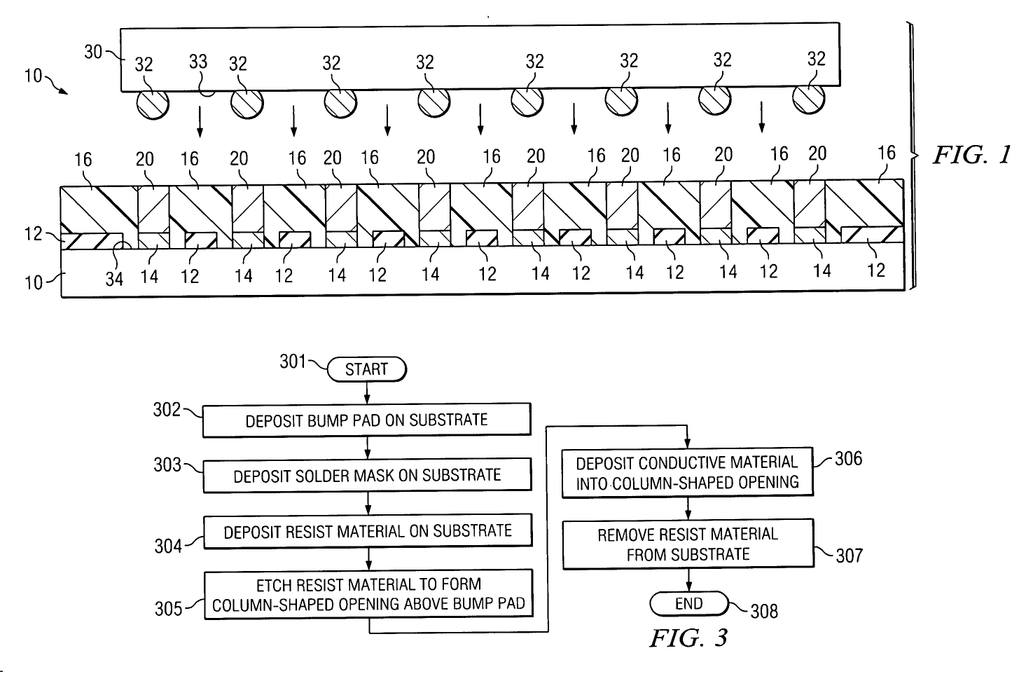

FIG. 1 illustrates flip chip assembly 100 in accordance with a particular embodiment of the present invention. Flip chip assembly 100 is a flip chip in which a column of conductive material has been deposited above each of the bump pads on the surface of the substrate. These columns increase the stand-off height between the die and the substrate. This helps to reduce the stress experienced at the connection between the solder bumps and die of the flip chip assembly due to any mismatch in the CTEs of the two materials, and facilitates the insertion of an underfill material into the gap between the die and substrate.

As shown in FIG. 1, flip chip assembly 100 includes die 30 and substrate 10, which are positioned generally parallel with, and spaced apart from, each other.

Substrate 10 is typically constructed using ceramic or organic materials. A plurality of bump pads 14 are disposed on the upper surface of substrate 10 and are operable to provide a electrical connection between die and an external device (not illustrated) when electrically coupled with die 30. Packaging die 30 this way allows for greater package density, while at the same time offering improved heat dissipation, high self-alignment, and tighter assembly tolerances.

Flip chip assembly 100 also includes solder mask 12, which is disposed upon the upper surface of substrate 10, and which defines an opening around each of the plurality of bump pads 14.

Flip chip assembly 100 also includes resist material 16 disposed on top of substrate 10 and solder mask 12. Resist material 16 defines a column-shaped opening over each of the plurality of bump pads 14. This column-shaped opening is at least partially filled with a conductive material, such as copper or solder. This conductive material forms a column 20 above each of the plurality of bump pads 14, essentially increasing the height of the bump pads 14.

Flip chip assembly 100 also includes a plurality of solder bumps 32 disposed between die 30 and substrate 10. These solder bumps 32 typically comprise eutectic tin-lead (Sn/Pb) or high lead (Pb) composition solders, although other solders and solder compositions may be used as well.

Generally, the plurality of solder bumps 32 is first applied to die 30 in a process referred to as “bumping”. In this process, solder bumps 32 are connected to the interconnect layer (not illustrated) on the lower face 33 of die 30. Die 30 and the attached solder bumps 32 are then positioned over substrate 10 such that each solder bump 32 is aligned with a corresponding bump pad 14/column 20 on upper face 34 of substrate 10, in what is referred to as a “pick and flip” operation. With the plurality of solder bumps 32 disposed between, and in contact with, the interconnect layer of die 30 and the bump pads 14/column 20 on substrate 10, a rigid connection may be formed between die 30 and substrate assembly 10 by reflowing and then solidifying the plurality of solder bumps 32.

Of course, as illustrated in FIG. 1, flip chip assembly 100 is shown prior to die 30 being coupled with substrate 10 by way of solder bumps 32 being reflowed and then solidified. It should be recognized by one skilled in the art that once flip chip assembly 100 is fully assembled, die 30 is actually coupled with substrate 10 by way of the solder bumps 32 on the face of the die assembly.

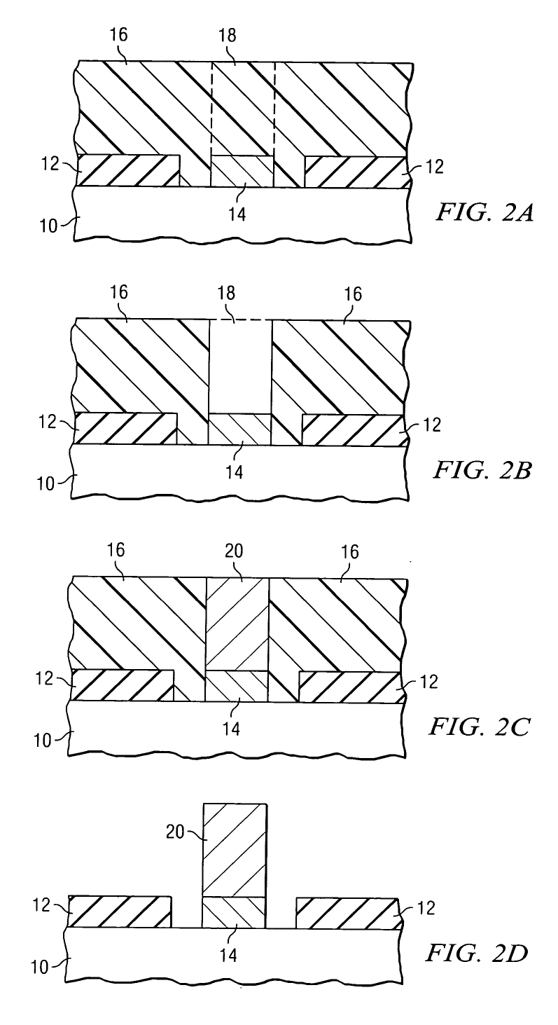

A better understanding of the present invention is available by making reference to FIGS. 2A-2D, which illustrate various stages in the fabrication of flip chip assembly 100. Each of FIGS. 2A-2D illustrate a close-up side-view of substrate 10, showing the area around a single bump pad 14/column 20.

As shown in FIG. 2A, bump pad 14 is disposed upon the upper surface of substrate 10. Bump pad 14 may include a number of conductive materials known in the art, such as a copper pad, and connects to circuitry within substrate 10 that allows substrate 10 to electrically couple die 30 (FIG. 1) with an external device (not illustrated).

Flip chip assembly 100 also includes solder mask 12, which is also disposed upon the upper surface of substrate 10. This is typically a photo-imageable material that has been etched so that the solder mask 12 defines an opening around bump pad 14.

As illustrated in FIGS. 1-2D, bump pad 14 is a non-solder mask defined (NSMD) pad, meaning the diameter of the opening defined by solder mask 12 is larger than the diameter of bump pad 14 such that there is clearance between bump pad 14 and solder mask 12. It should be recognized, however, that bump pad 14 could also be a solder mask defined (SMD) pad, a SMD pad being one in which the diameter of bump pad 14 is larger than the opening defined by solder mask 12 such that the area of bump pad 14 that is exposed is defined by the opening in the solder mask.

Above substrate 10, bump pad 14, and solder mask 12, a layer of resist material 16 is disposed, covering the substrate, bump pad, and solder mask. Resist material 16 may be selected from a number of materials, including photo-imageable and laser-processible materials. The use of these types of materials allow resist material 16 to etched or drilled to either reveal portions of the solder mask 12, bump pad 14, or substrate 10 beneath the material, or to remove the material entirely.

As such, with resist material 16 in place, a section of the material is removed over bump pad 14 to re-expose the pad. This is shown in FIG. 2B. As mentioned above, the removal of this material may be accomplished by etching or drilling a column-shaped opening 18 into resist material 16 above bump pad 14.

A conductive material is then inserted into column-shaped opening 18 to form column 20. This conductive material may include copper, solder, or some other metal that has been deposited into opening 18, such as by plating or printing.

With the column 20 in place above bump pad 14, the remainder of resist material 16 may be optionally removed, such as by etching, leaving column 20 of in place over bump pad 14, as shown in FIG. 2D. By placing column 20 over bump pad 14, column 20 essentially increases the effective height of bump pad 14, in some cases by over 50 μm.

It should be recognized, however, that resist material 16 need not be removed in every embodiment of the present invention. In particular embodiments of the present invention, resist material 16 may be left in place above solder mask 12. In these embodiments, resist material 16 may be chosen to approximate the physical characteristics of an underfill material (not illustrated) that will be inserted into the flip chip assembly between the die and the substrate. This allows resist material 16 to be left in place above solder mask 12 without creating any undue stress on the coupling between die 30 and substrate 10. Examples of specific properties that are typically desirable to approximate include the CTE and glass transition temperature of the underfill. Depending on the application, other properties may be approximated, as well. In fact, depending on the specific embodiment, resist material 16 may be selected to be the same material as the underfill. With resist material 16 chosen to approximate the properties of the underfill material, upon insertion and cooling of the underfill material, resist material 16 and the underfill may act as essentially one layer.

By increasing the effective height of bump pads 14 with the addition of column 20 the stand-off height of flip chip assembly 100 (FIG. 1) is increased. This helps to reduce the stress experienced at the connection between silicon chip 30 and solder bump 32, improving the reliability of the flip chip.

Increasing the stand-off height also helps to ease the insertion of underfill between die 30 (FIG. 1) and substrate 10, further helping to strengthen the connection between the die and substrate, as well as providing a barrier to moisture and/or other contaminants.

Similar to the process discussed above, FIG. 3 illustrates a flowchart of a method for increasing bump pad height in accordance with a particular embodiment of the present invention.

After starting in block 301, a plurality of bump pads are deposited on the surface of the substrate in block 302. A solder mask is then deposited on the substrate such that the solder mask defines an opening around each of the bump pads.

A resist material, such as a photo-imageable or laser-processible material, is then deposited on the substrate, on top of the solder mask and bump pads in block 304, such that the solder mask and bump pads are completely covered.

The resist material is then etched in block 305. In this process a column-shaped opening is formed above each bump pad such that the bump pad is re-exposed.

A conductive material is then deposited into plurality of column-shaped openings in block 306. This material may include a conductive metal, such as copper, that has been plated into the opening, or a solder that has been deposited into the opening. Once solidified, the conductive material essentially increases the effective height of the bump pad, in some embodiments over 50 μm above the bump pad.

Lastly, with the conductive material in place over the bump pad, the remainder of the resist material may be optionally removed in block 307 before the process terminates in block 308.

Although particular embodiments of the method and apparatus of the present invention have been illustrated in the accompanying drawings and described in the foregoing detailed description, it will be understood that the invention is not limited to the embodiments disclosed, but is capable of numerous rearrangements, modifications, and substitutions without departing from the spirit of the invention as set forth and defined by the following claims.

1. A method for increasing bump pad height in a flip chip, comprising:
depositing a bump pad on a substrate;
depositing a solder mask on the substrate to define an opening surrounding the bump pad;
depositing a resist material on the substrate such that the resist material covers the bump pad and solder mask;
removing a portion of the resist material above the bump pad to form a column-shaped opening above the bump pad;
depositing a conductive material into the column-shaped opening above the bump pad to form a column-shaped conductor;
providing a flip chip having a first surface with a solder bump attached thereon; and
positioning the first surface against the substrate and aligning the solder bump to the top of the column-shaped conductor to make a electrically conductive joint.

2. The method of claim 1, further comprising:
removing the resist material forming the column-shaped opening from the substrate.

3. The method of claim 1, wherein the bump pad comprises a solder mask defined (SMD) bump pad.

4. The method of claim 1, wherein the bump pad comprises a non-solder mask defined (NSMD) bump pad.

5. The method of claim 1, wherein the resist material comprises a photo-resist material.

6. The method of claim 1, wherein the resist material comprises a patterning material.

7. The method of claim 1, wherein the resist material comprises a photo-imageable material.

8. The method of claim 1, wherein the resist material comprises a laser-processible material.

9. The method of claim 1, wherein the resist material is selected to approximate the coefficient of thermal expansion of an underfill material.

10. The method of claim 1, wherein the resist material is selected to approximate the glass transition temperature of an underfill material.

11. The method of claim 1, wherein the resist material comprises an underfill material.

12. The method of claim 1, wherein the conductive material comprises solder.

13. The method of claim 1, wherein the conductive material comprises copper.

14. The method of claim 1, wherein depositing a conductive material into the column-shaped opening comprises plating copper into the column-shaped opening.

15. The method of claim 1, wherein the conductive material extends at least 50 μm above the bump pad.

16. A flip chip assembly, comprising:
a bump pad deposited on a substrate;
a solder mask deposited on the substrate, defining an opening around the bump pad;
a resist material deposited on the substrate over the solder mask, defining a column-shaped opening above the bump pad; and
a conductive material deposited in the column-shaped opening above the bump pad.

17. The assembly of claim 16, wherein the bump pad comprises a solder mask defined (SMD) bump pad.

18. The assembly of claim 16, wherein the bump pad comprises a non-solder mask defined (NSMD) bump pad.

19. The assembly of claim 16, wherein the resist material comprises a photo-resist material.

20. The assembly of claim 16, wherein the resist material comprises a patterning material.

21. The assembly of claim 16, wherein the resist material comprises a photo-imageable material.

22. The assembly of claim 16, wherein the resist material comprises a laser-processible material.

23. The assembly of claim 16, wherein the resist material is selected to approximate the coefficient of thermal expansion of an underfill material.

24. The assembly of claim 16, wherein the resist material is selected to approximate the glass transition temperature of an underfill material.

25. The assembly of claim 16, wherein the resist material comprises an underfill material.

26. The assembly of claim 16, wherein the conductive material comprises solder.

27. The assembly of claim 16, wherein the conductive material comprises copper.

28. The assembly of claim 27, wherein the copper is plated into the column-shaped opening.

29. The assembly of claim 16, wherein the conductive material extends at least 50 μm above the bump pad.

30. A flip chip assembly, comprising:
a bump pad deposited on a substrate;
a solder mask deposited on the substrate, defining an opening around the bump pad;
a column of conductive material deposited above the bump pad;
the column of conductive material being deposited into a column-shaped opening in a resist material deposited over the bump pad and solder mask;
the resist material being at least partially removed following the deposition of the conductive material.

31. The assembly of claim 30, wherein the bump pad comprises a solder mask defined (SMD) bump pad.

32. The assembly of claim 30, wherein the bump pad comprises a non-solder mask defined (NSMD) bump pad.

33. The assembly of claim 30, wherein the resist material comprises a photo-resist material.

34. The assembly of claim 30, wherein the resist material comprises a patterning material.

35. The assembly of claim 30, wherein the resist material comprises a photo-imageable material.

36. The assembly of claim 30, wherein the resist material comprises a laser-processible material.

37. The assembly of claim 30, wherein the conductive material comprises solder.

38. The assembly of claim 30, wherein the conductive material comprises copper.

39. The assembly of claim 30, wherein the copper is plated into the column-shaped opening.

40. The assembly of claim 30, wherein the conductive material extends at least 50 μm above the bump pad.
